(19) United States
(12) Patent Application Publication
(10) Pub. No.: US 2008/0001614 A1
(43) Pub. Date: Jan. 3, 2008

(54) Image Capture Device with Alignment Indicia

(76) Inventor: Dean E. Thorson, Grayslake, IL (US)

Correspondence Address: PHILIP H. BURRUS, IV, 460 Grant Street, Atlanta, GA, 30312, US

(21) Appl. No.: 11/427,198

(22) Filed: Jun. 28, 2006

(51) Int. Cl. G01R 31/02

(52) U.S. Cl. 324/760

(57) ABSTRACT

A burn-in board for burn-in and electrical testing of a plurality of integrated circuit devices that is disposed in one or more processing trays may include a substrate having an interface surface and a plurality of electrical contacts disposed on the interface surface for establishing, through engagement with the one or more processing trays, electrical communication between the leads of the integrated circuit devices and a tester. One or more ports may be defined in the substrate so as to extend between the interface surface and another surface of the substrate wherein the port or ports are sized and configured to enable application of a negative pressure between the substrate and the one or more processing trays upon engagement of the substrate therewith and upon application of a vacuum through the one or more ports.

### BACKGROUND

1. Technical Field

This invention relates generally to image capture devices, and more specifically to an image capture device having an alignment indicia indicative of a subject's position relative to the boundaries of an image.

2. Background Art

Telecommunications technology is continually advancing. While once a caller had to talk to an operator at a central exchange just to place a call, today millions of people take mobile telephones everywhere they go. People use these devices to send and receive voice and data instantly around the globe.

One of the newest telecommunication technologies available today is that of the video teleconference call. In a video teleconference call, a video image of the caller is transmitted along with the caller's voice. Other participants of the call are then able to see, as well as hear, the speaking party.

One problem with video conference calls is that video teleconference devices generally only have a single display. Thus, when party A calls party B, B's image is displayed on A's video teleconference device. Consequently, A is unable to determine whether he is aligned with his camera.

Turning now to FIG. 1, illustrated therein is a prior art teleconference system 100. Party A 101 is engaging party B 102 in a video teleconference call. Party A 101 uses a video teleconference device 103 having a camera 105 and a display 107, in addition to conventional audio communication devices. Similarly, party B 102 uses a teleconference device 104 having a camera 106 and a display 108. Each camera 105,106 takes an image within its field of view 109,110. The picture taken by each camera 105,106 is then transmitted through a telecommunication network 112 to the other teleconference device.

By way of example, camera 106 takes an image of party B 102. This image 113 is then displayed on party A's display 107. Since each party is seeing an image of the other, neither can determine if they are centered with respect to their camera. For instance, the field of view 109 of party A's camera 105 is not aligned with party A 101. Consequently, the image 114 party B sees is partially party A, and partially background 111. The only way for party A 101 to determine whether he is aligned is to ask, “Can you see me?” Party B 102 must then respond with directives until party A 101 can be seen on party B's display 108. This process is time consuming and cumbersome.

One solution to this problem is to provide two screens on each teleconference device. A first screen would show the incoming image, while the second screen would show a local image. The problem with this solution, however, is that it requires a doubling of many device components. This doubling not only makes the teleconference device large and bulky, but also increases the overall cost of the device considerably.

An alternate solution is to overlay the local image on a portion of the single display, competing for area with the incoming image. The problem with this solution is that it requires an increase in the display area of the device, which also increases the size and overall cost of the device considerably.

There is thus a need for an improved image capture alignment device and method.

### BRIEF DESCRIPTION OF THE DRAWINGS

FIG. 1 illustrates a prior art teleconference system.

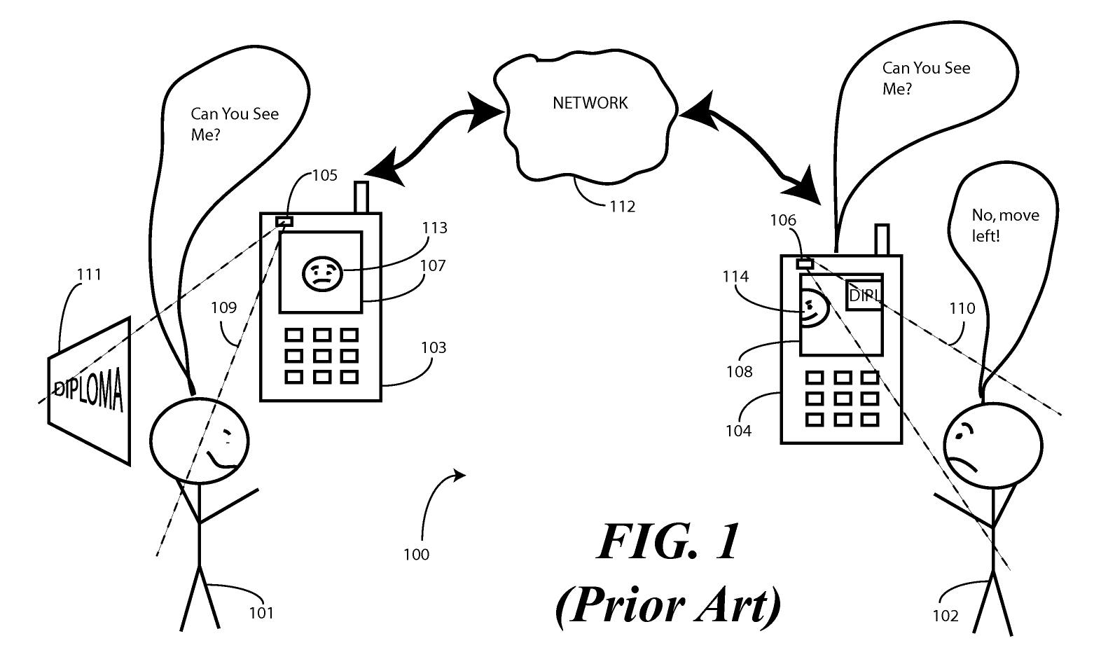

FIG. 2 illustrates one embodiment of an image capture device in accordance with the invention.

FIGS. 3 and 4 illustrate one embodiment of an alignment indicia on an image capture device indicating subject alignment in accordance with the invention.

FIGS. 5, 6, and 7 illustrate various embodiments of alignment indicia in accordance with the invention.

FIG. 8 illustrates an exemplary teleconference employing image capture devices in accordance with the invention.

FIG. 9 illustrates one embodiment of a method for determining subject alignment with an image capture device in accordance with the invention.

FIG. 10 illustrates one embodiment of a sub-method for determining subject alignment with an image capture device in accordance with the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

Before describing in detail embodiments that are in accordance with the present invention, it should be observed that the embodiments reside primarily in combinations of method steps and apparatus components related to presenting indicia of subject alignment on an image capture device. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

It will be appreciated that embodiments of the invention described herein may be comprised of one or more conventional processors and unique stored program instructions that control the one or more processors to implement, in conjunction with certain non-processor circuits, some, most, or all of the functions of presenting alignment indicia on an image capture device as described herein. The non-processor circuits may include, but are not limited to, a radio receiver, a radio transmitter, signal drivers, clock circuits, power source circuits, and user input devices. As such, these functions may be interpreted as steps of a method to perform the presentation of alignment indicia. Alternatively, all functions could be implemented by a state machine that has no stored program instructions, or in one or more application specific integrated circuits, in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and circuits with minimal experimentation.

Embodiments of the invention are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” In this document, relational terms such as first and second, top and bottom, and the like may be used solely to distinguish one entity or action from another entity or action without necessarily requiring or implying any actual such relationship or order between such entities or actions. Also, reference designators shown herein in parenthesis indicate components shown in a figure other than the one in discussion. For example, talking about a device (10) while discussing figure A would refer to an element, 10, shown in figure other than figure A.

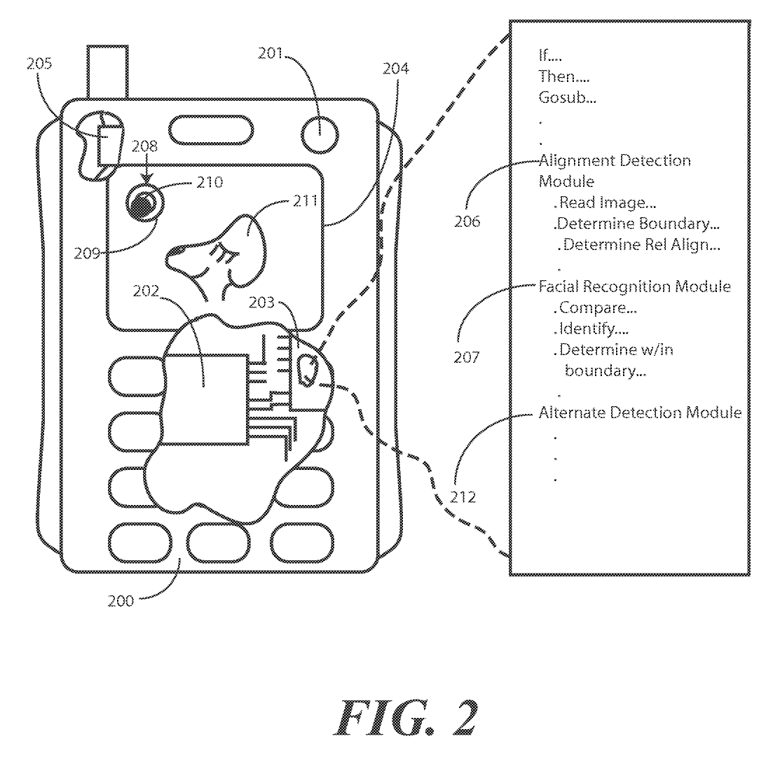

Turning now to FIG. 2, illustrated therein is one embodiment of an image capture apparatus 200 in accordance with the invention. For the purposes of discussion, the exemplary embodiment of FIG. 2 is that of a telecommunication device, as one application for the present invention is teleconference calling. However, it will be clear to those of ordinary skill in the art having the benefit of this disclosure that the invention is not so limited. Other devices, including portable and desktop computers, landline telephones, gaming devices, and the like may also employ alignment indicia in accordance with the invention.

The image capture apparatus 200 includes an image capture device 201. The image capture device 201 may be any of a variety of electronic image capture devices, including digital cameras, charge-coupled device image sensors, and CMOS image sensors. The image capture device 201 has associated therewith a field of view, within which objects will appear in captured images. Objects outside the field of view will not appear in captured images.

A control circuit 202 is coupled to the image capture device 201. The control circuit 202, which may be a microprocessor or embedded controller, may serve as a control device for both the image capture device 201 and the overall image capture apparatus 200. The control circuit 202 may also include associated memory 203 for storing data and an executable instruction set.

A display 204 is provided for presenting images to a user. Where the image capture apparatus 200 is a two-way communication device like a mobile telephone, the display 204 may be used for presenting either locally captured images or those received through the transceiver 205 from remote sources. In one embodiment, the control circuit 202 is configured to present the various images on the display 204.

The image capture apparatus 200 includes various modules for its operation and function execution. These modules, which may comprise control circuit instructions stored in memory 203 as embedded firmware code, are responsible for the various applications operating within the image capture apparatus 200.

In one embodiment of the invention, the image capture apparatus 200 includes an alignment detection module 206. The alignment detection module 206, which is operable with the processor, is configured to determine the relative alignment of a subject with respect to the image capture device 201. While the determination of alignment will be described in more detail below, the alignment detection module 206 examines one or more captured images from the image capture device 201 to determine whether a subject object of interest is within the boundaries of the captured image. Said differently, the alignment detection module 206 determines whether the subject is within the field of view when an image is captured.

In one embodiment of the invention, a facial recognition module 207 is used to determine subject alignment with the image capture device 201. The facial recognition module 207 is configured to determine the relative alignment of the subject with the image capture device 201 by identifying at least one facial feature. By way of example, the facial recognition module 207 may identify a facial feature such as the nose, eyes, or mouth. Once identified, the alignment detection module 206 may determine if this facial feature is sufficiently within the boundaries of the image, i.e. whether the facial feature is sufficiently within the field of view of the image capture device 201.

Once the alignment detection module 206 determines whether the facial feature, or the subject itself, is within the boundary of the image captured by the image capture device 201, the control circuit 202 presents indicia 208 on the display 204 indicating the relative alignment of a subject with respect to the image capture device 201. In one embodiment, which will be described in more detail below, the indicia 208 comprises an image boundary indicator 209 and a subject indicator 210. As the subject moves relative to the image capture device's field of view, the subject indicator 210 moves relative to the image boundary indicator 209, thereby providing the user with a small, quick, accurate indication of his position relative to the image capture device 201. In one embodiment, the indicia 208, which may resemble a bubble gauge, is substantially transparent and is capable of being superimposed atop an image 211 on the display 204.

Facial recognition systems, which are well known in the art, operate by identifying a person or feature from a digital image through comparison of selected facial features between the image and features stored in memory. While highly reliable, there may be instances, due to lighting or other external conditions, where the facial recognition module 207 fails to properly identify or converge on a particular feature. As such, in one embodiment, the image capture apparatus 200 also includes an alternate detection module 212. The alternate detection module 212, which may work on differences between consecutive images, differences in color or tint in a single image, or another detection system, may be employed where a facial recognition system fails to determine the relative alignment of the subject with the image capture device 201.

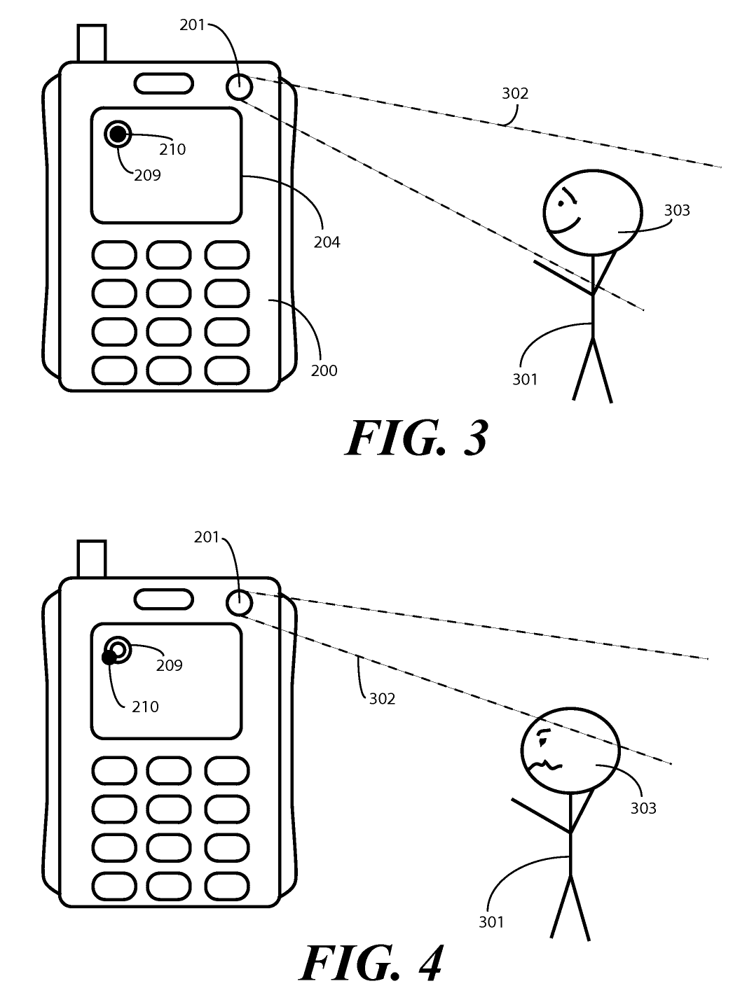

Turning now to FIGS. 3 and 4, illustrated therein is the image alignment in action. In FIG. 3, the subject 301 has a subject object of interest 303, i.e. the subject's head, within the field of view 302 of the image capture device 201. Consequently, the subject object of interest 303 falls within the boundary of an image captured by the image capture device 201. As such, on the indicia 208 presented on the display, the subject indicator 210 is within the boundary indicator 209.

In FIG. 4, the subject object of interest 303 is only partially within the field of view 302 of the image capture device 201. Thus, the subject object of interest 303 will not entirely be within an image captured by the image capture device 201. To indicate this, the subject indicator 210 is moved partially outside the boundary indicator 209, thereby alerting the subject 301 that he must move either the subject object of interest 303 or the image capture device 201 for proper alignment.

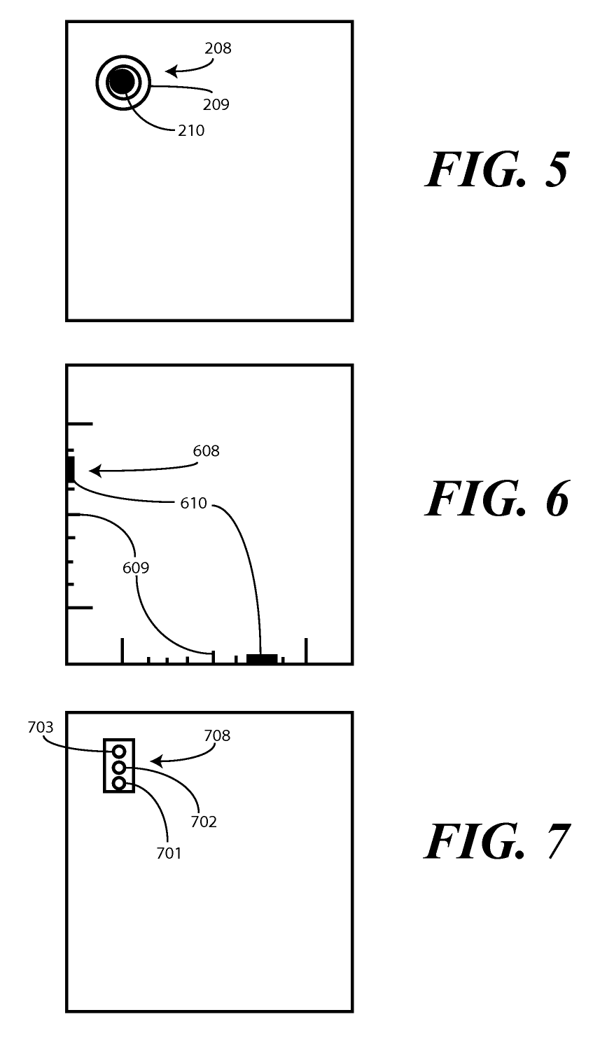

Turning now to FIGS. 5, 6, and 7, illustrated therein are various embodiments of indicia for alignment in accordance with the invention. In FIG. 5, an indicia 208 as described above includes a subject indicator 210 and a boundary indicator 209. Shown here as a circle within concentric circles, the subject indicator 210 and boundary indicator 209 comprise a visual representation of a bubble gauge, where the subject indicator 210 operates as a bubble, and the boundary indicator 209 operates as a gauge. To provide further indication of alignment, the subject indicator 210 may further change color as the subject, or subject object of interest, moves relative to the image capture device (201). For instance, when centered, the subject indicator 210 may be a first color, transitioning to a second color when not centered.

In FIG. 6, the indicia 608 has a boundary indicator 609 comprising a vertical gauge and a horizontal gauge. As the subject moves relative to the image capture device (201), subject indicators 610 move relative to the boundary indicators 609.

In FIG. 7, the indicia 708 is color-coded. Shown in exemplary form as a traffic light, a green light 701 indicates subject/image capture device alignment; a yellow light 702 indicates partial subject/image capture device alignment; and a red light 703 indicates subject/image capture device misalignment. Thus, the indicia 708 changes color as the subject moves relative to the image capture device.

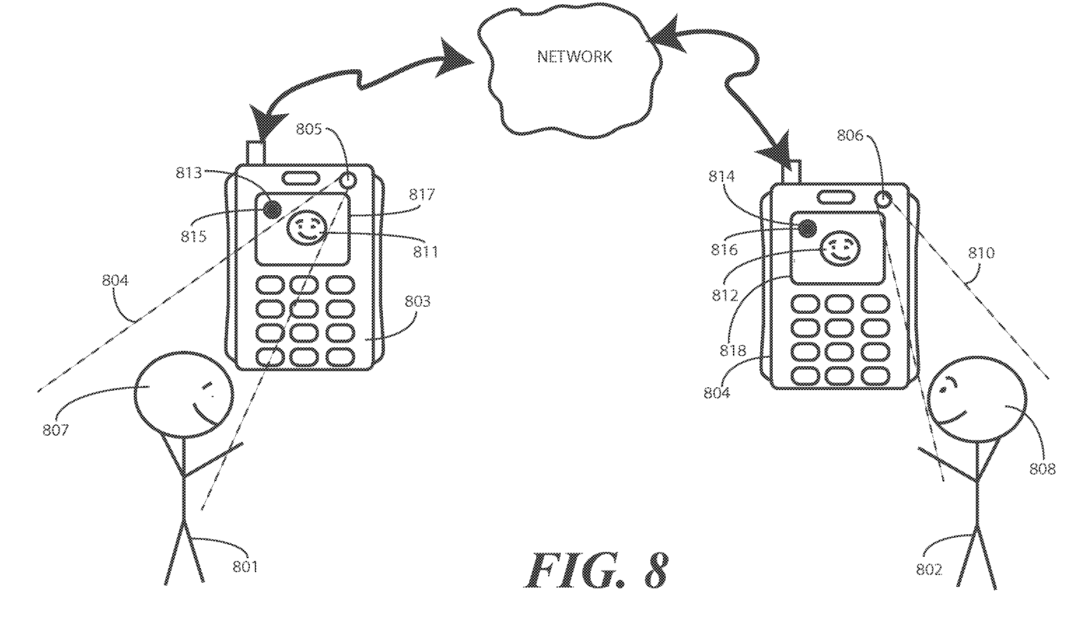

Turning now to FIG. 8, illustrated therein are two parties 801,802 utilizing image capture apparatuses 803,804 in accordance with one embodiment of the invention for a video teleconference. The image capture apparatuses 803,804 shown in FIG. 8 are mobile telephones, having digital cameras as image capture devices.

Subject 801 has his head 807 aligned with image capture device 805's field of view 804, as indicated by the subject indicator 813 being centered within the boundary indicator 815 of apparatus 803. Similarly, subject 802 has his head 808 aligned within the field of view 810 of image capture device 806, as indicated by the subject indicator 814 being centered within the boundary indicator 816 of apparatus 804. As such, each image 811,812 appears on the other apparatus 804,803.

In the embodiment of FIG. 8, each indicia 805,806 is a visual overlay disposed atop images 811,812 receive from a remote host 803,804. Each visual overlay is semi-transparent, and is superimposed over the received image 811,812. Thus, upon presenting images from the remote host on the display modules 817,818, control circuits within the apparatuses 803,804 concurrently present the indicia on the display 817,818 of the relative alignment of each subject 801,802 with respect to his image capture device 805,806.

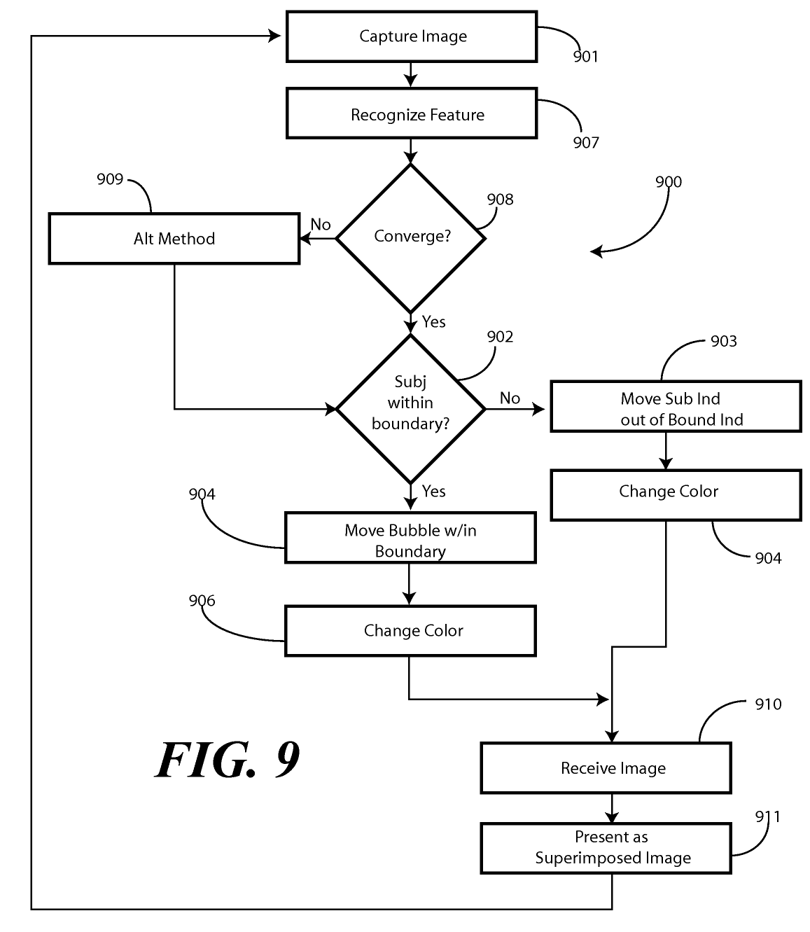

Turning now to FIG. 9, illustrated therein is one embodiment of a method 900 of alerting a subject of a relative position with respect to an image capture device in accordance with the invention. At step 901, a local image capture device captures at least one image of a subject. At decision 902, a detection module determines whether the subject, or a subject object of interest, is disposed within a boundary of the image. Where it is, at step 904, the detection module presents indicia of the subject or subject object of interest relative to the boundary of the image. This may include moving a subject indicator within a boundary indicator. Alternatively, a color of the indicia may be changed as indicated at 906.

Where the subject is not disposed within the boundary of the image, at step 903 the detection module presents indicia indicating such on a display. This may include moving a subject indicator partially or completely outside a boundary indicator. Alternatively, a color of the indicia may be changed, perhaps from a first color indicating alignment to a second color indicating misalignment.

In one embodiment of the method, the detection module determines whether the subject or subject object of interest is within the boundary of the image by recognizing the subject or subject object of interest by facial recognition. This optional indication mechanism is indicated at step 907. Where facial recognition is employed, an alternate method of determining may be included as a contingent method where facial recognition is unsuccessful in identifying the subject or subject object of interest. Where this is the case, the detection module may determine whether facial recognition was successful at decision 908. If unsuccessful, the detection module may actuate the alternative detection system at step 909.

As described above, in one embodiment, an image capture apparatus comprises a two-way communication device suitable for use as a video teleconference device. In such an embodiment, the device may receive electronically images from a remote host at step 910. The device may then present the images from the remote host on the display, and superimpose the indicia of the subject object of interest relative to the boundary of the image atop the image from the remote host at step 911. The indicia may then be continually updated with subject movement throughout the video teleconference call.

In recording video, many images are captured per second. For instance, in standard video systems, 60 images per second are captured. Analyzing each of these images to determine subject alignment may be unnecessary, as subject movement is often slow when compared to the image capture rate. Additionally, analyzing 3600 images per minute consumes a good deal of processing power.

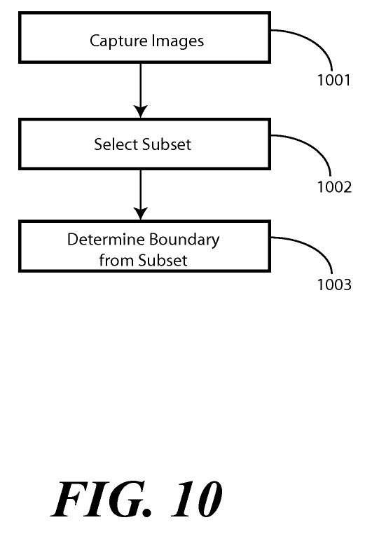

Turning now to FIG. 10, a sub-method of the method 900 of FIG. 9 is illustrated, the sub-method providing a method of determining subject alignment with an image capture device with less processing power. At step 1001, a plurality of images required for video are captured. At step 1002, the detection module selects a subset of these images for analysis. For example, the subset may be one image of every three images, one of every ten images, one of every sixty images, and so forth. At step 1003, the detection module determines whether the subject or subject object of interest is disposed within the boundary of the image by analyzing only the subset of images. Further criteria may be added as well. For example, prior to moving a subject indicator, the detection module may require that the subject is misaligned with the image capture device for at least a predetermined number of images, or for at least a predetermined portion of analyzed images.

In the foregoing specification, specific embodiments of the present invention have been described. However, one of ordinary skill in the art appreciates that various modifications and changes can be made without departing from the scope of the present invention as set forth in the claims below. Thus, while preferred embodiments of the invention have been illustrated and described, it is clear that the invention is not so limited. Numerous modifications, changes, variations, substitutions, and equivalents will occur to those skilled in the art without departing from the spirit and scope of the present invention as defined by the following claims. Accordingly, the specification and figures are to be regarded in an illustrative rather than a restrictive sense, and all such modifications are intended to be included within the scope of present invention.

1. A system for testing integrated circuit devices disposed in processing trays, comprising:
a burn-in board having a plurality of electrical contacts located and configured for establishing direct electrical contact with a plurality of integrated circuit devices disposed in at least one of the processing trays;
a tray source configured to deliver processing trays adjacent the burn-in board;
a displacement mechanism configured to move the burn-in board and the at least one processing tray into mutual engagement; and
a tester in electrical communication with the plurality of electrical contacts.

2. The system of claim 1, further comprising an apparatus for sorting the plurality of integrated circuit devices responsive to testing thereof.

3. The system of claim 1, further comprising a system controller configured for controlling the operation of the tray source, the displacement mechanism, and the tester.

4. The system of claim 1, further comprising an environmental chamber sized and configured to receive the burn-in board and the at least one processing tray in engagement therewith during testing.

5. A system for testing integrated circuit devices disposed in processing trays, comprising:
a burn-in board having an interface surface;
a tray source configured to deliver at least two of the processing trays adjacent the burn-in board;
a plurality of electrical contacts disposed on the interface surface located and configured for establishing direct electrical contact with integrated circuit devices disposed in one of the at least two processing trays;
at least one other plurality of electrical contacts disposed on the interface surface located and configured for establishing direct electrical contact with integrated circuit devices disposed in another of the at least two processing trays;
a displacement mechanism configured to move the burn-in board and the at least two of the processing trays into mutual engagement; and
a tester electrically coupled to the plurality of electrical contacts and to the at least one other plurality of electrical contacts.

6. The system of claim 5, further comprising an apparatus for sorting the integrated circuit devices responsive to testing thereof.

7. The system of claim 5, further comprising a system controller configured for controlling the operation of the tray source, the displacement mechanism, and the tester.

8. The system of claim 5, further comprising an environmental chamber sized and configured to receive the burn-in board and the at least two of the processing trays in engagement therewith during testing.

9. A test system for burn-in and electrical testing of integrated circuit devices disposed in processing trays, comprising:
a burn-in board including an interface surface and an electrical conduit;
a tray source configured to deliver at least one processing tray adjacent the burn-in board;
at least one plurality of electrical contacts disposed on the interface surface located and configured to establish direct electrical contact with integrated circuit devices disposed in the at least one processing tray, the at least one plurality of electrical contacts electrically coupled to the electrical conduit;
a displacement mechanism configured to move the burn-in board and the at least one processing tray into mutual engagement;
a tester in electrical communication with the electrical conduit; and
a system controller operably coupled to the tray source, the displacement mechanism, and the tester, and configured to control operation thereof.

10. The test system of claim 9, further comprising:
an environmental chamber sized and configured to receive the burn-in board and the at least one processing tray in engagement therewith during testing;
wherein the system controller is operably coupled to the environmental chamber and configured to control operation thereof.

11. The test system of claim 9, further comprising:
a sorting apparatus configured for sorting the integrated circuit devices responsive to testing thereof;
wherein the system controller is operably coupled to the sorting apparatus and configured to control operation thereof.

12. The test system of claim 9, further comprising:
at least one latching mechanism associated with the burn-in board and configured to attach the at least one processing tray to the burn-in board;
wherein the system controller is operably coupled to the at least one latching mechanism and is configured to control operation thereof.

13. A method of testing integrated circuit devices, comprising:
disposing the integrated circuit devices in a plurality of processing trays;
delivering at least one processing tray of the plurality of processing trays adjacent a burn-in board;
moving the burn-in board and the at least one processing tray into mutual engagement;
establishing electrical contact between the burn-in board and integrated circuit devices disposed in the at least one processing tray; and
measuring at least one electrical characteristic of the integrated circuit devices disposed in the at least one processing tray.

14. The method of claim 13, further comprising:
moving the burn-in board and the at least one processing tray away from one another to terminate the electrical contact between the burn-in board and the integrated circuit devices; and
delivering at least one other processing tray of the plurality of processing trays adjacent the burn-in board.

15. The method of claim 13, further comprising subjecting the integrated circuit devices disposed in the at least one processing tray to thermal cycling while measuring the at least one electrical characteristic.

16. The method of claim 13, further comprising sorting the integrated circuit devices dispose in the at least one processing tray according to the at least one electrical characteristic exhibited by each of the integrated circuit devices.

17. A method of performing burn-in and electrical testing of integrated circuit devices disposed in processing trays, comprising:
delivering at least one of the processing trays into a target zone proximate a burn-in board, the at least one processing tray having a plurality of the integrated circuit devices disposed thereon;
moving the burn-in board and the at least one processing tray into mutual engagement;
establishing electrical contact between the burn-in board and the plurality of the integrated circuit devices; and
measuring at least one electrical characteristic of the plurality of the integrated circuit devices.

18. The method of claim 17, further comprising:
moving the burn-in board and the at least one processing tray away from one another to terminate the electrical contact;
moving the at least one processing tray out of the target zone; and
delivering at least one other of the processing trays having a plurality of the integrated circuit devices disposed thereon into the target zone.

19. The method of claim 17, further comprising subjecting the plurality of the integrated circuit devices disposed in the at least one processing tray to thermal cycling while measuring the at least one electrical characteristic.

20. The method of claim 17, further comprising:
sorting the plurality of the integrated circuit devices disposed in the at least one processing tray into categories according to the at least one electrical characteristic exhibited by each integrated circuit device of the plurality of the integrated circuit devices; and
transferring the plurality of the integrated circuit devices to other transport media according to the categories.

21. The method of claim 17, further comprising:
providing a system controller;
controlling the acts of delivering at least one of the processing trays into a target zone proximate a burn-in board:
moving the burn-in board and the at least one processing tray into mutual engagement; and
measuring at least one electrical characteristic of the plurality of the integrated circuit devices, with the system controller.

22. The method of claim 19, further comprising:
providing a system controller;
controlling the acts of delivering at least one of the processing trays into a target zone proximate a burn-in board;
moving the burn-in board and the at least one processing tray into mutual engagement;
measuring at least one electrical characteristic of the plurality of the integrated circuit devices; and
subjecting the plurality of the integrated circuit devices disposed in the at least one processing tray to thermal cycling, with the system controller.

23. The method of claim 20, further comprising: providing a system controller;
controlling the acts of delivering at least one of the processing trays into a target zone proximate a burn-in board;
moving the burn-in board and the at least one processing tray into mutual engagement;
measuring at least one electrical characteristic of the plurality of the integrated circuit devices;
sorting the plurality of the integrated circuit devices; and
transferring the plurality of the integrated circuit devices, with the system controller.

24. A system for testing integrated circuit devices disposed in processing trays, comprising:
at least two test assemblies, each test assembly of the at least two test assemblies including a burn-in board in mutual engagement with at least one of the processing trays, the burn-in board including a plurality of electrical contacts located and configured for establishing direct electrical contact with a plurality of the integrated circuit devices disposed in the at least one processing tray;
a test frame including at least two test bays, each test bay of the at least two test bays configured to receive and support one of the at least two test assemblies and to establish electrical contact therewith; and
a tester in electrical communication with the at least two test assemblies.

25. The test system of claim 24, further comprising at least one latching mechanism disposed in each of the at least two test assemblies and configured to secure the burn-in board and the at least one processing tray in the mutual engagement.

26. The test system of claim 24, further comprising:
an assembly apparatus configured to effect the mutual engagement between the burn-in board and the at least one processing tray to form each test assembly, and further configured to move test assembly to one of the at least two test bays on the test frame;
a tray source configured to deliver the processing trays to the assembly apparatus; and
a burn-in board source configured to deliver the burn-in boards to the assembly apparatus.

27. The test system of claim 26, further comprising a system controller operably coupled to the tester, the assembly apparatus, the tray source, and the burn-in board source, and configured to control operation thereof.

28. The test system of claim 24, further comprising an environmental chamber sized and configured to receive the test frame.

29. A system for testing integrated circuit devices disposed in processing trays, comprising:
a plurality of burn-in boards, each burn-in board of the plurality of burn-in boards including an interface surface and a plurality of electrical contacts disposed on the interface surface, the plurality of electrical contacts located and configured for establishing direct electrical contact with integrated circuit devices disposed in at least one of the processing trays, the each burn-in board further including an electrical conduit electrically connected to the plurality of electrical contacts;
an assembly apparatus configured to secure one of the plurality of burn-in boards and at least one of the processing trays in mutual engagement to form a test assembly;
a test frame configured to receive a plurality of the test assemblies, the test frame including at least one shelf configured to support at least one of the test assemblies and further including at least one connector configured for electrical connection to at least one of the electrical conduits; and
a tester electrically coupled to the at least one connector on the test frame.

30. The test system of claim 29, further comprising:
at least one other plurality of electrical contacts disposed on the interface surface of each burn-in board, the at least one other plurality of electrical contacts located and configured for establishing direct electrical contact with integrated circuit devices disposed in at least one other of the processing trays, the electrical conduit on each burn-in board electrically connected to the at least one other plurality of electrical contacts;
wherein the assembly apparatus is configured to secure each burn-in board, the at least one processing tray, and the at least one other processing tray in mutual engagement to form one of the test assemblies.

31. The test system of claim 29, further comprising:
a tray source configured to deliver the processing trays to the assembly apparatus;
a burn-in board source configured to deliver the plurality of burn-in boards to the assembly apparatus; and
an environmental chamber sized and configured to receive the test frame and the plurality of the test assemblies received in the test frame.

32. The test system of claim 31, further comprising a system controller operably coupled to the assembly apparatus, the tester, the tray source, the burn-in board source, and the environmental chamber, and configured to control operation thereof.

33. A test assembly for testing integrated circuit devices
disposed in processing trays, comprising:
a burn-in board having an interface surface;
a plurality of electrical contacts disposed on the interface surface located and configured for establishing direct electrical contact with a plurality of integrated circuit devices disposed in at least one of the processing trays;
at least one latching mechanism securing the at least one processing tray and the burn-in board in mutual engagement, thereby establishing direct electrical contact between the plurality of electrical contacts and the plurality of integrated circuit devices; and
an electrical conduit electrically connected to the plurality of electrical contacts and configured for electrically coupling the plurality of electrical contacts to a test frame.

34. The test assembly of claim 33, further comprising at least one alignment surface disposed on the burn-in board configured, by contact with the at least one processing tray, to align the at least one processing tray with respect to the burn-in board.

35. A test assembly for testing a plurality of integrated circuit devices disposed in a plurality of cells arranged in a pattern on a processing tray, comprising:
a burn-in board including an interface surface and further including a plurality of footprints disposed on the interface surface arranged substantially congruent with the pattern, each footprint of the plurality of footprints comprising a plurality of electrical contacts located and configured for establishing direct electrical contact with a plurality of leads extending from one integrated circuit device of the plurality of integrated circuit devices;
at least one latching mechanism securing the burn-in board and the processing tray in mutual engagement, thereby aligning each integrated circuit device of the plurality of integrated circuit devices disposed in the processing tray with one footprint of the plurality of footprints; and
an electrical conduit electrically connected to the plurality of footprints and configured for electrically coupling each footprint to a test frame.

36. A method of testing integrated circuit devices disposed in processing trays, comprising:
securing each of the processing trays in mutual engagement with a burn-in board to form a plurality of test assemblies;
establishing electrical contact between the burn-in board and a plurality of integrated circuit devices disposed in each processing tray;
disposing each test assembly of the plurality of test assemblies in an individual test bay of a test frame and supporting each test assembly therein;
electrically couplings each test assembly to a test instrument; and
measuring at least one electrical characteristic of the integrated circuit devices.

37. The method of claim 36, further comprising subjecting the integrated circuit devices disposed in the plurality of test assemblies to thermal cycling while measuring the at least one electrical characteristic.

38. The method of claim 36, further comprising aligning each processing tray of the plurality of processing trays with respect to the burn-in board.

39. The method of claim 36, further comprising: providing a system controller;
controlling the acts of securing each processing tray in mutual engagement with a burn-in board;
disposing each test assembly in an individual test bay of the test frame; and
measuring at least one electrical characteristic of the integrated circuit devices, with the system controller.

40. The method of claim 37, further comprising:
providing a system controller;
controlling the acts of securing each processing tray in mutual engagement with a burn-in board;
disposing each test assembly in an individual test bay of the test frame;
subjecting the integrated circuit devices disposed in the plurality of test assemblies to thermal cycling; and
measuring at least one electrical characteristic of the integrated circuit devices, with the system controller.
